(19) United States
(12) Patent Application Publication
(10) Pub. No.: US 2022/0252508 A1
(43) Pub. Date: Aug. 11, 2022

(54) LIGHT EMITTING APPARATUS, LIGHT EMITTING METHOD, SPECTROMETER AND SPECTRUM DETECTION METHOD

(71) Applicant: MEGA CRYSTAL BIOTECHNOLOGY SINGAPORE PTE. LTD, SINGAPORE (SG)

(72) Inventors: Yi-Sheng TING, New Taipei City (TW); Yu-Tsung CHEN, New Taipei City (TW); Po-Sung CHEN, New Taipei City (TW)

(21) Appl. No.: 17/728,262

(22) Filed: Apr. 25, 2022

Related U.S. Application Data
(63) Continuation of application No. 16/891,580, filed on Jun. 3, 2020.

(30) Foreign Application Priority Data
Sep. 18, 2019 (CN) 201910882229.5
Feb. 14, 2020 (TW) 109104834

(51) Int. Cl. G01N 21/31; H01L 25/13; G01N 21/359; H01L 33/50

(52) U.S. Cl. CPC G01N 21/3103; H01L 25/13; G01N 2201/062; H01L 33/50; G01N 21/359

(57) ABSTRACT

A light emitting apparatus has a plurality of light emitting units, and each of them emits a light with a light emission peak wavelength and a wavelength range. The wavelength ranges of the two light emitting units with the two adjacent light emission peak wavelengths are partially overlapped or non-overlapped. Each of the light emitting units discontinuously emits a light with a lighting frequency. The present disclosure further provides the spectrometer, a light emitting method and a spectrum detection method, and all of them utilizes the light emitting apparatus, a background noise is discarded and a frequency domain signal of an optical spectrum signal of a tested object is reserved, so as to have a filtering effect and achieve high test accuracy, which can replace conventional spectrometer for wavelength resolution characteristics.

### CROSS REFERENCE

The present invention is Continued Application of U.S. patent application Ser. No. 16/891,580 filed on 2020 Jun. 3, wherein all contents of the references which priorities are claimed by the present invention are included in the present invention, herein.

### TECHNICAL FIELD

The present disclosure relates to a light emitting apparatus, in particularly to, a light emitting apparatus which is able to select a wavelength range, a difference between adjacent light emission peak wavelengths, full widths at half maximum and lighting frequencies of lights emitted by light emitting diodes (LED), and further to a light emitting method, a spectrometer and a spectrum detection method which utilize the light emitting apparatus.

### RELATED ART

Spectrometers can be used to measure the transmitted light through the object or the reflected light on the surface of the object, and the conventional spectrometer usually includes a light source and a monochromator, wherein the light source can be a halogen gas-filled tungsten filament lamp (halogen tungsten lamp) to produce a continuous spectrum of Vis-near IR (visible light-near infrared light) with an emission spectrum of about 320 nm to 2500 nm. Next, the monochromator composed of a prism or a grating selects a monochromatic light of a specific wavelength for the absorption or reflection measurement of the sample (or called tested object), which of course also includes continuous scanning within the set wavelength range to analyze the absorption optical spectrum or reflection optical spectrum of the sample. However, as the problems of the tungsten filament lamp mentioned by the issued patent of CN101236107B, due to the high calorific value and high temperature of the tungsten filament lamp, when using the tungsten filament lamp as a light source for organic product testing such as agricultural products, food, pharmaceuticals, petrochemical products, high temperature will cause qualitative changes in organic samples, which seriously affects the test results. The disclosure in the aforementioned the issued patent of CN101236107B is included in the present disclosure.

The issued patent of CN101236107B discloses the light source of the spectrometer can be multiple light emitting diodes (LEDs). Each LED emits a monochromatic spectrum with a different wavelength range. In addition to combining the aforementioned multiple LEDs into a continuous spectrum, according to the design, merely the LED corresponding to the wavelength range is turned on when merely the monochromatic light of a certain wavelength range is needed. That is, the multiple LEDs can be turned on at the same time to form a continuous optical spectrum, and the LEDs can be sequentially turned on according to corresponding to the wavelength ranges which are needed to be scanned. However, the issued patent of CN101236107B focuses the emission light beams of the LEDs on the entrance slit of the monochromator, and thus the problem of the high manufacturing cost and high system complexity of the monochromator cannot be solved. The issued patent of CN205388567U utilizes the assembly of LEDs and fibers to replace monochromator, and further utilizes a full reflection mirror to increase the light path length to enhance the sample detecting efficiency. The disclosure in the aforementioned the issued patent of CN205388567U is included in the present disclosure, and the issued patent of CN109932335A further discloses the similar technology.

Although the aforementioned three patents have improved the problems of traditional spectrometer's light source heating and monochromator cost. However, the wavelength resolution (usually greater than 10 nm) of the spectroscopy using the LED array as the light source in the third patent mentioned above is lower than the wavelength resolution (usually 1 nm) of the conventional spectrometer using halogen lamps and monochromator. It causes doubts about the three patents that utilize the LED array as the light source to correctly analyze the optical spectrum of the sample. Another problem of the three patents is that the signal-to-noise ratio (SNR or S/N) cannot be improved. The aforementioned three patented utilizes the LED arrays to replace tungsten halogen lamps as light sources. In addition, they have not changed other operation of the light source, so obviously there is no improvement in the SNR caused by the light source end, and the aforementioned three patents cannot further improve SNR.

### SUMMARY

The main objective of the present disclosure is to provide a light emitting apparatus composed of a plurality of LEDs emitting lights with different wavelength ranges from each other and a spectrometer composed of the light emitting apparatus. The analysis result of the spectrometer of the present disclosure for a sample is close to the high analysis results of the conventional tungsten halogen spectrometer, and at the same time, the present disclosure improves the signal-to-noise ratio in the optical spectrum of the test results of the sample, so as to achieve the high accuracy of the test.

To achieve the above objective, the present disclosure provides a light emitting apparatus, the light emitting apparatus at least comprises a plurality of light emitting units, and each of them emits a light with a light emission peak wavelength and a wavelength range. The wavelength ranges of the two light emitting units with the two adjacent light emission peak wavelengths are overlapped to form a continuous wavelength range which is wider than each of the wavelength ranges of the two light emitting units with the two adjacent light emission peak wavelengths, or alternatively, the wavelength ranges of the two light emitting units with the two adjacent light emission peak wavelengths are non-overlapped; the two adjacent light emission peak wavelengths have a wavelength difference being larger than or equal to 1 nm, and at least one portions of the light emission peak wavelengths have full widths at half maximum being larger than 0 nm and less than or equal to 60 nm.

In one embodiment of the present disclosure, all of the light emission peak wavelengths have full widths at half maximum being larger than 0 nm and less than or equal to 60 nm.

In one embodiment of the present disclosure, the light emitting unit is a light emitting diode, a vertical-cavity surface-emitting laser or a laser diode.

In one embodiment of the present disclosure, each of the light emitting units discontinuously emits the light with a lighting frequency, and all of the lighting frequencies are identical to or different from each other, or partial of the lighting frequencies are identical to or different from each other.

In one embodiment of the present disclosure, the lighting frequency is 0.05-500 times/second.

In one embodiment of the present disclosure, associated with the lighting frequency, a time interval for turning on the light emitting unit is 0.001-10 seconds.

In one embodiment of the present disclosure, associated with lighting frequency, a time interval for turning off the light emitting unit is 0.001-10 seconds.

In one embodiment of the present disclosure, the two adjacent light emission peak wavelengths have the wavelength difference being 1-80 nm.

In one embodiment of the present disclosure, the two adjacent light emission peak wavelengths have the wavelength difference being 5-80 nm.

In one embodiment of the present disclosure, each of the full widths at half maximum of the corresponding light emission peak wavelength is 15-50 nm.

In one embodiment of the present disclosure, each of the full widths at half maximum of the corresponding light emission peak wavelength is 15-40 nm.

In one embodiment of the present disclosure, the light emitting unit comprises a light emitting die, and the light emitting dies are covered by a wavelength conversion layer, the wavelength conversion layer comprises a plurality of wavelength conversion regions, each of the wavelength conversion regions corresponds to one of the light emitting dies.

In one embodiment of the present disclosure, all or partial of the light emitting dies are identical to each other, or all of the light emitting dies are different from each other.

In one embodiment of the present disclosure, all or partial of the wavelength conversion regions comprise identical or different fluorescent powders, quantum dot materials or nonlinear crystals.

In one embodiment of the present disclosure, the wavelength conversion layer is a film layer, and the wavelength conversion regions are consecutive to form the film layer; or, the two adjacent wavelength conversion regions of the film layer are separated from a spacer.

To achieve the above objective, the present disclosure further provides a spectrometer which at least comprises a light source controller, the above light emitting apparatus, one or more photodetectors and a computer. The light source controller is electrically connected to the light emitting apparatus, the photodetector is electrically connected to the computer, the photodetector receives a light beam emitted by the light emitting apparatus, and a propagation path of the light beam between the light emitting apparatus and photodetector forms a light path.

In one embodiment of the present disclosure, a mathematical analysis module is installed in the photodetector or the computer, the mathematical analysis module is electrically or signally connected to the photodetector or the computer, the mathematical analysis module is a hardware or software based module, and a signal collected by the photodetector is transmitted to the mathematical analysis module; in the time interval for turning on the light emitting unit, associated with the lighting frequency, the signal collected by the photodetector is a combination signal of a background noise and an optical spectrum signal of the tested object; in the time interval for turning off the light emitting unit, associated with the lighting frequency, the signal collected by the photodetector is the background noise; the combination signal forms a time domain signal of the tested object, and the mathematical analysis module comprises a time domain/frequency domain transformation unit for transforming the time domain signal of the tested object to a frequency domain signal of the tested object.

In one embodiment of the present disclosure, the time domain/frequency domain transformation unit is a Fourier transform unit for transforming the time domain signal of the tested object to the frequency domain signal of the tested object via a Fourier transformation.

In one embodiment of the present disclosure, the frequency domain signal of the tested object comprises a frequency domain signal of the optical spectrum signal of the tested object and a frequency domain signal of the background noise, the mathematical analysis module discards the frequency domain signal of the background noise and reserves the frequency domain signal of the optical spectrum signal of the tested object, the mathematical analysis module further comprises a frequency domain/time domain transformation unit for transforming the reserved frequency domain signal of the optical spectrum signal of the tested object to the filtered time domain signal of the tested object.

In one embodiment of the present disclosure, the frequency domain/time domain transformation unit is an inverse Fourier transform unit for transforming the reserved frequency domain signal of the optical spectrum signal of the tested object to the filtered time domain signal of the tested object via an inverse Fourier transformation.

In one embodiment of the present disclosure, the tested object is disposed on the light path, and the light beam of the light path is reflected by a surface of the tested object, and the light emitting apparatus and the photodetector are disposed on one side of the tested object, so as to measure a reflection optical spectrum of the tested object; the light beam emitted by the light emitting apparatus comprises an emission light beam, and the emission light beam passing through a top surface of the tested object is refracted to form an inner refraction light beam which enters interior of the tested object; the inner refraction light beam passing through the interior of the tested object reaches an internal diffuse point to form a penetration depth, and the penetration depth is a longest distance from the top surface to the interior of the tested object which the inner refraction light beam can reach; the inner refraction light beam forms an inner diffuse light beam at the internal diffuse point with the penetration depth, the inner diffuse light beam passing through a surface refraction point of the top surface is refracted to form an inner light beam of the tested object, the photodetector is disposed on a propagation path of the inner light beam of the tested object, and the inner light beam of the tested object is received by the photodetector.

In one embodiment of the present disclosure, the spectrometer has a light blocking part for blocking light, the light blocking part contacts the top surface and is disposed between the surface reflection point and the surface refraction point.

In one embodiment of the present disclosure, the top surface is a curved surface, and the light emitting apparatus closely contacts the top surface; or alternatively, the spectrometer has a light blocking part which the light beam cannot pass through, and the light blocking part masks the light emitting apparatus and exposes an exit of the emission light beam.

In one embodiment of the present disclosure, the photodetector closely contacts the top surface; or alternatively, the spectrometer has a light blocking part which the light beam cannot pass through, and the light blocking part masks photodetector and exposes an entrance of the inner light beam of the tested object.

In one embodiment of the present disclosure, the emission light beam comprises the lights of different wavelength ranges, the spectrometer has multiple photodetectors, and the photodetectors disposed on different positions of the top surface.

In one embodiment of the present disclosure, the emission light beam comprises the lights of different wavelength ranges, and the spectrometer has merely one of the photodetector, and the photodetector is disposed on different positions of the top surface in turn.

The present disclosure also provides a light emitting method comprising sequential steps as follows: a light emitting unit providing step: providing a plurality of light emitting units, each of them emits a light with a light emission peak wavelength and a wavelength range, wherein the wavelength ranges of the two light emitting units with the two adjacent light emission peak wavelengths are overlapped to form a continuous wavelength range which is wider than each of the wavelength ranges of the two light emitting units with the two adjacent light emission peak wavelengths, or alternatively, the wavelength ranges of the two light emitting units with the two adjacent light emission peak wavelengths are non-overlapped; the two adjacent light emission peak wavelengths have a wavelength difference being larger than or equal to 1 nm, at least one portions of the light emission peak wavelengths have full widths at half maximum being larger than 0 nm and less than or equal to 60 nm; and a light emission step: controlling each of the light emitting units to discontinuously emit the light with a lighting frequency, wherein the lighting frequency is 0.05-500 times/second, associated with the lighting frequency, a time interval for turning on the light emitting unit is 0.001-10 seconds, and a time interval for turning off the light emitting unit is 0.001-10 seconds.

The present disclosure further provides a spectrum detection method which comprises the steps of the above light emitting method and a filtering step. The filtering step is described as follows: an optical spectrum signal of the tested object and a background noise are received, in the time interval for turning on the light emitting unit; associated with the lighting frequency, the signal collected by the photodetector is a combination signal of the background noise and the optical spectrum signal of the tested object; in the time interval for turning off the light emitting unit, associated with the lighting frequency, the signal collected by the photodetector is the background noise; the combination signal forms a time domain signal of the tested object, the time domain signal of the tested object is transformed to a frequency domain signal of the tested object via a Fourier transformation: the frequency domain signal of the tested object comprises a frequency domain signal of the optical spectrum signal of the tested object and a frequency domain signal of the background noise, the frequency domain signal of the background noise is discarded, and the frequency domain signal of the optical spectrum signal of the tested object is reserved.

In one embodiment of the present disclosure, the spectrum detection method further comprises an inverse transformation step, and the inverse transformation step transforms the reserved frequency domain signal of the optical spectrum signal of the tested object to the filtered time domain signal of the tested object via an inverse Fourier transformation.

In one embodiment of the present disclosure, the spectrum detection method utilizes the above spectrometer for detection.

The present disclosure utilizes the light emitting units to make the two adjacent light emission peak wavelengths have a wavelength difference being larger than or equal to 1 nm, and to make the light emission peak wavelengths have full widths at half maximum being larger than 0 nm and less than or equal to 60 nm. The light emitting units discontinuously emit the lights with lighting frequencies, and the time domain signal of the tested object is transformed to a frequency domain signal of the tested object via a Fourier transformation. The frequency domain signal of the tested object comprises a frequency domain signal of the optical spectrum signal of the tested object and a frequency domain signal of the background noise, the frequency domain signal of the background noise is discarded, and the frequency domain signal of the optical spectrum signal of the tested object is reserved. Therefore, the filtering effect is achieved to increase the test accuracy, and wavelength resolution characteristics of the light emitting apparatus and the spectrometer of the present disclosure can replace wavelength resolution characteristics of the conventional spectrometer.

### DESCRIPTIONS OF DRAWINGS

FIG. 1 is a first schematic diagram showing implementations of a light emitting apparatus and a spectrometer of the present disclosure.

FIG. 2 is schematic diagram showing an emission optical spectrum of a LED according to a first embodiment of the present disclosure.

FIG. 3 is schematic diagram showing an emission optical spectrum of a LED according to a second embodiment of the present disclosure.

FIG. 4 is schematic diagram showing an emission optical spectrum of a LED according to a third embodiment of the present disclosure.

FIG. 5A is a second schematic diagram showing implementations of a light emitting apparatus and a spectrometer of the present disclosure.

FIG. 5B is a third schematic diagram showing implementations of a light emitting apparatus and a spectrometer of the present disclosure.

FIG. 6A is a schematic diagram showing a time domain signal of a tested object measured by a spectrometer of the present disclosure.

FIG. 6B is a schematic diagram showing a frequency domain signal of a tested object after the time domain signal of the tested object measured by the spectrometer of the present disclosure is performed with a Fourier transformation.

FIG. 6C is a schematic diagram showing a filtered time domain signal of a tested object after the reserved frequency domain signal of the optical spectrum signal of the tested object filtered by the spectrometer is performed with an inverse Fourier transformation.

FIG. 7A is a schematic diagram showing reflection optical spectrums of zinc oxide and a mixture of the zinc oxide and iron oxide of a first comparative example, which are measured by a conventional spectrometer.

FIG. 7B is a schematic diagram showing reflection optical spectrums of zinc oxide and a mixture of the zinc oxide and iron oxide of a first application example, which are measured by a spectrometer of the present disclosure.

FIG. 7C is a schematic diagram showing reflection optical spectrums of zinc oxide and a mixture of the zinc oxide and iron oxide of a second application example, which are measured by a spectrometer of the present disclosure.

FIG. 7D is a schematic diagram showing reflection optical spectrums of zinc oxide and a mixture of the zinc oxide and iron oxide of a third application example, which are measured by a spectrometer of the present disclosure.

FIG. 8 is flowchart of a light emitting method of the present disclosure.

FIG. 9 is flowchart of a spectrum detection method of the present disclosure.

FIG. 10A is a first schematic diagram showing an implementation of a light emitting unit of the present disclosure.

FIG. 10B is a second schematic diagram showing an implementation of a light emitting unit of the present disclosure.

FIG. 11A is a first schematic diagram showing an implementation which the light emitting dies of the present disclosure are formed on an array substrate in a rectangular fashion.

FIG. 11B is a second schematic diagram showing an implementation which the light emitting dies of the present disclosure are formed on an array substrate in a rectangular fashion.

FIG. 12 is a third schematic diagram showing an implementation which the light emitting dies of the present disclosure are formed on an array substrate in a rectangular fashion.

FIG. 13A is a schematic diagram of an implementation which the spectrometer of the present disclosure measures a reflection optical spectrum signal of the tested object.

FIG. 13B is a schematic diagram of an implementation which the inner light spectrum signal of the tested object is measured.

FIG. 13C is a schematic diagram of an implementation which the spectrometer of the present disclosure further has a light blocking part.

FIG. 14A is a first schematic diagram showing an implementation which the inner light spectrum signal of the tested object with a curved surface is measured.

FIG. 14B is a second schematic diagram showing an implementation which the inner light spectrum signal of the tested object with a curved surface is measured.

FIG. 14C is a schematic diagram showing an implementation which the inner light spectrum signals of the tested object with different inner depths are measured by photodetectors installed in the spectrometer.

FIG. 14D is a schematic diagram showing an implementation which the inner light spectrum signals of the tested object with different inner depths are measured by merely one photodetector installed in the spectrometer.

### DETAILS OF EXEMPLARY EMBODIMENTS

The following describes the implementation of the present invention by exemplary embodiments. Those skilled in the art can easily understand other advantages and effects of the present disclosure from the contents disclosed in this specification. It should be noted that the structure, ratio, size, and etc., shown in the drawings in this specification are only used to explain the contents disclosed in the specification, for those familiar with this technology to understand and read, not to limit the present disclosure. The above limitations that can be implemented may not have any technical significance. Any structural modifications, changes in proportional relationship or size adjustments should still fall within the scope of the technical content disclosed by the present disclosure, without affecting the effectiveness and the purpose of the present disclosure.

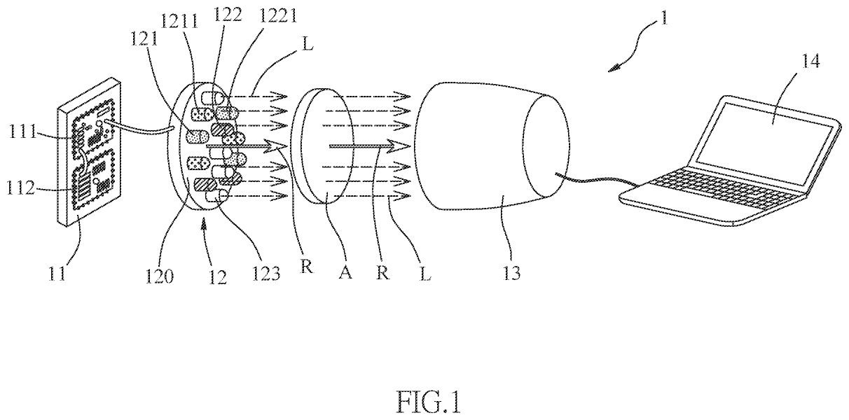

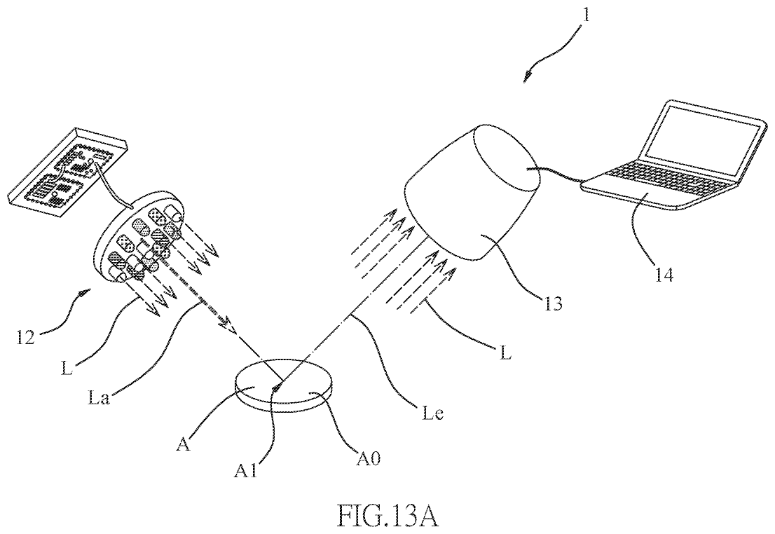

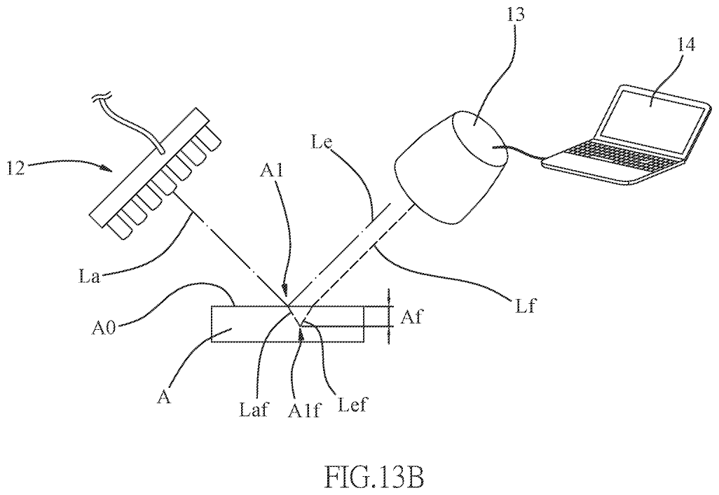

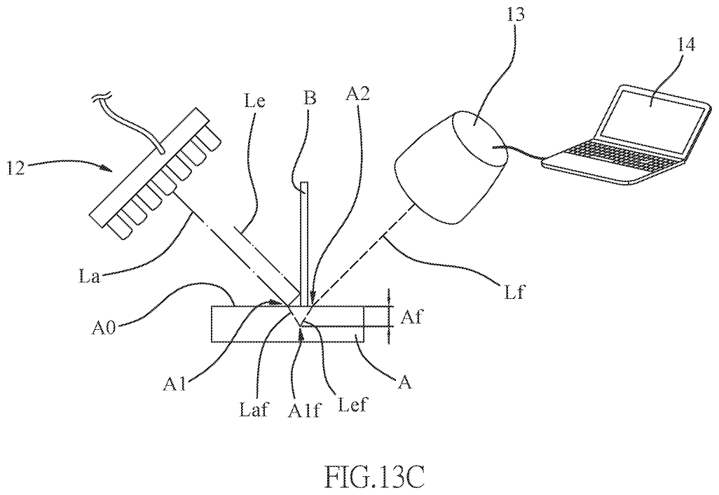

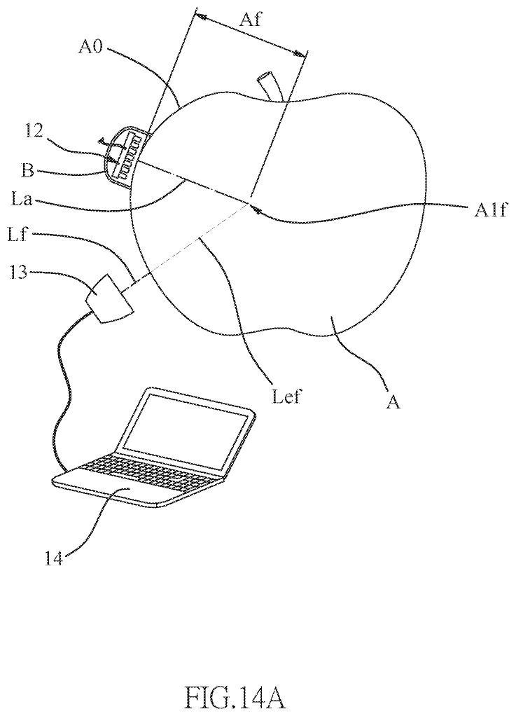

Firstly, refer to an embodiment of FIG. 1, the light emitting apparatus 12 is used in a spectrometer 1, and the spectrometer 1 comprises a light source controller 11, a light emitting apparatus 12, a photodetector 13 and a computer 14. The light source controller 11 is electrically connected to the light emitting apparatus 12 and an external power source (not shown in drawings), the photodetector 13 1 is electrically connected to the computer 14, the photodetector 13 receives a light beam L emitted by the light emitting apparatus 12, and a propagation path of the light beam L between the light emitting apparatus 12 and the photodetector 13 forms a light path R. The photodetector 13 can be a photomultiplier, a photoconducting detector or a Si bolometer. A tested object A is disposed on the light path R, and the light of the light path R passes through the tested object A or is reflected on the surface of the tested object A. In FIG. 1, the light of the light path R passes through the tested object A, so as to measure the absorption optical spectrum of the tested object A. In addition, in the implementation which the light of the light path R is reflected on the surface of the tested object A, the reflection optical spectrum of the tested object A is measured (see FIG. 13A). The photodetector 13 converts the light beam L into an optical spectrum signal of the tested object A, and the optical spectrum signal of the tested object A is transmitted to the computer 14, and the computer 14 converts the optical spectrum signal of the tested object A to an optical spectrum of the tested object A. The computer 14 can be a personal computer, a notebook or a server.

The light emitting apparatus 12 at least comprises a plurality of light emitting units, and each of them emits a light with a light emission peak wavelength and a wavelength range. The light emission peak wavelength or the wavelength range is 300-2500 nm, wherein the light emitting unit can be a light emitting diode (LED), a vertical-cavity surface-emitting laser (VCEL) or a laser diode (LD). In the following embodiments, the light emitting unit can be the LED, but the present disclosure is not limited thereto. The people who are skilled in the art can know the LED, VCEL and LD in the present disclosure are interchangeable, and this will not affect the dedicated results and implementations of the present disclosure. In the embodiment of FIG. 1, the light emitting apparatus 12 comprises three LEDs 121-123, the first LED 121 emits a first light beam with a first wavelength range, the second LED 122 emits a second light beam with a second wavelength range, and the third LED 123 emits a third light beam with a third wavelength range. The first light beam has a first light emission peak wavelength within the first wavelength range, the second light beam has a second light emission peak wavelength within the second wavelength range, and the third light beam has a third light emission peak wavelength within the third wavelength range. The first LED 121, the second LED 122 and the third LED 123 are electrically connected to a circuit board 120 of the light emitting apparatus 12, and the circuit board 120 is electrically connected to the light source controller 11. In other words, the light source controller 11 is electrically connected to the first LED 121, the second LED 122 and the third LED 123, and the light source controller 11 can control the first LED 121, the second LED 122 and the third LED 123 to be turned on or off (bright or dark, powered on or powered off). That is, the light source controller 11 controls multiple LEDs to be turned on or off (bright or dark). Preferably, the light source controller 11 controls the first LED 121, the second LED 122 and the third LED 123 continuously or discontinuously radiate. That is, the light source controller 11 controls multiple LEDs to continuously or discontinuously radiate. More preferably, the light source controller 11 controls the first LED 121, the second LED 122 and the third LED 123 to discontinuously radiate with lighting frequencies. That is, the light source controller 11 controls the LEDs to discontinuously radiate with lighting frequencies. The lighting frequencies can be identical to or different from each other. For example, the light source controller 11 comprises a microcontroller unit electrically connected to the external power source and a clock generator electrically connected to the microcontroller unit 111. The lighting frequencies are generated by the clock generator 112, the signals of the lighting frequencies are transmitted to the microcontroller unit 111, and then the microcontroller unit 111 controls the LEDs (such as, the first LED 121, the second LED 122 and the third LED 123) electrically connected to the microcontroller unit 111 to be turned on or off according to the lighting frequencies. It is noted that, the clock generator 112 for generating the lighting frequencies can be a clock generation module integrated in the microcontroller unit 111. The clock generation module can be implemented by a software or a hardware, and thus it does not need to set the clock generator on the exterior of the microcontroller unit 111. It is noted that, according to the technical features of the light source controller 11, based upon the actual requirements, the LEDs are turned on or off at the same time, or one or partial LEDs are selected to turned on or off, or the LEDs are turned on or off in turn, or the LEDs are turned on or off by using one of the above manners with the lighting frequency.

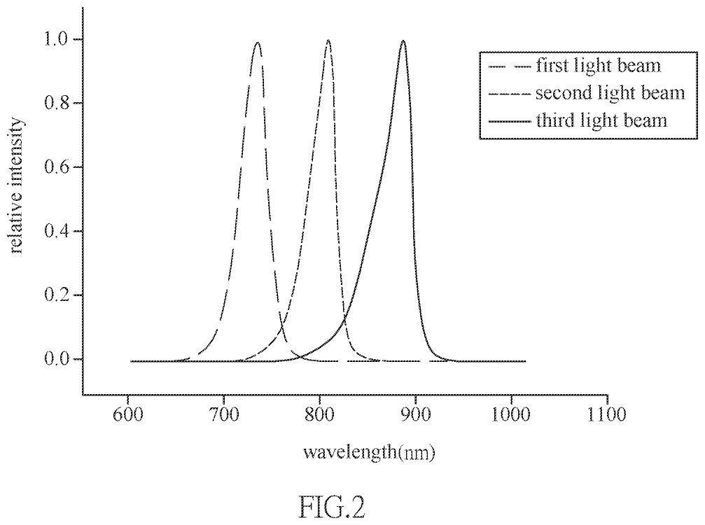

Refer to the first embodiment of FIG. 2, the wavelength ranges of the two light emitting units with the two adjacent light emission peak wavelengths are overlapped to form a continuous wavelength range which is wider than each of the wavelength ranges of the two light emitting units with the two adjacent light emission peak wavelengths, and the continuous wavelength range is 300-2500 nm. In FIG. 2, there are three light emission peak wavelengths and three corresponding wavelength ranges, and they are “the first light emission peak wavelength (734 nm) and the corresponding first wavelength range of the first light beam”, “the second light emission peak wavelength (810 nm) and the corresponding second wavelength range of the second light beam” and “the third light emission peak wavelength (882 nm) and the corresponding third wavelength range of the third light beam”. The first light emission peak wavelength and the second light emission peak wavelength are two adjacent light emission peak wavelengths, and similarly, the second light emission peak wavelength and the third light emission peak wavelength are two adjacent light emission peak wavelengths. The first wavelength range corresponding to the first light emission peak wavelength is 660-780 nm, the second wavelength range corresponding to the second light emission peak wavelength is 710-850 nm, thus the first wavelength range and the second wavelength range are overlapped within 710-780 nm, and the first wavelength range and the second wavelength range forms the continuous wavelength range of 660-850 nm. Similarly, the second wavelength range corresponding to the second light emission peak wavelength is 710-850 nm, the third wavelength range corresponding to the third light emission peak wavelength is 780-940 nm, thus the second wavelength range and the third wavelength range are overlapped within 780-850 nm, and the second wavelength range and the third wavelength range forms the continuous wavelength range of 710-940 nm. In the present disclosure, the overlapped portion of the wavelength ranges of the two light emitting units with the two adjacent light emission peak wavelengths is preferred to be less. Further, the wavelength ranges of the two light emitting units with the two adjacent light emission peak wavelengths can be non-overlapped in other embodiments, which are illustrated in the later descriptions.

The two adjacent light emission peak wavelengths have a wavelength difference being larger than or equal to 1 nm, preferably, 1-80 nm, and more preferably, 5-80 nm. In FIG. 2, the first light emission peak wavelength (734 nm) and the second light emission peak wavelength (810 nm) have the wavelength difference being 76 nm, and the second light emission peak wavelength (810 nm) and the third light emission peak wavelength (882 nm) have the wavelength difference being 72 nm. It is noted that, the numerical range of the present disclosure usually comprises two end values, and the wavelength difference being 5-80 nm of the two adjacent light emission peak wavelengths means the wavelength difference is larger than or equal to 5 nm, and less than and equal to 80 nm.

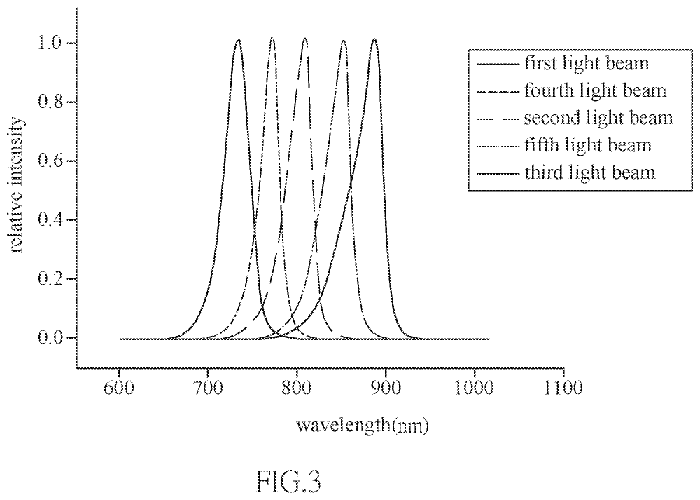

Refer to the second embodiment of FIG. 3, the second embodiment is modified from the first embodiment, and similar parts of the second embodiment and the first embodiment are not described again. The difference between the second embodiment and the first embodiment is that the light emitting apparatus 12 comprises five LEDs 121, 1211, 122, 123, 1221. The first through third LEDs 121-123 emit the first through third light beams with the first through wavelength ranges, the fourth and fifth LED 1211, 1221 emit the fourth and fifth light beams with the fourth and fifth wavelength ranges. The fourth light beam has the fourth light emission peak wavelength (772 nm) in the fourth wavelength range, and the fifth light beam has the fifth light emission peak wavelength (854 nm) in the fifth wavelength range. In FIG. 3, the light emission peak wavelengths are respectively the first light emission peak wavelength (734 nm), the fourth light emission peak wavelength (772 nm), the second light emission peak wavelength (810 nm), the fifth light emission peak wavelength (854 nm) and the third light emission peak wavelength (882 nm) in an increment order. The first light emission peak wavelength (734 nm) and the fourth light emission peak wavelength (772 nm) being adjacent to each other have the wavelength difference being 38 nm, the fourth light emission peak wavelength (772 nm) and the second light emission peak wavelength (810 nm) being adjacent to each other have the wavelength difference being 38 nm, the second light emission peak wavelength (810 nm) and the fifth light emission peak wavelength (854 nm) being adjacent to each other have the wavelength difference being 44 nm, and the fifth light emission peak wavelength (854 nm) and the third light emission peak wavelength (882 nm) being adjacent to each other have the wavelength difference being 28 nm.

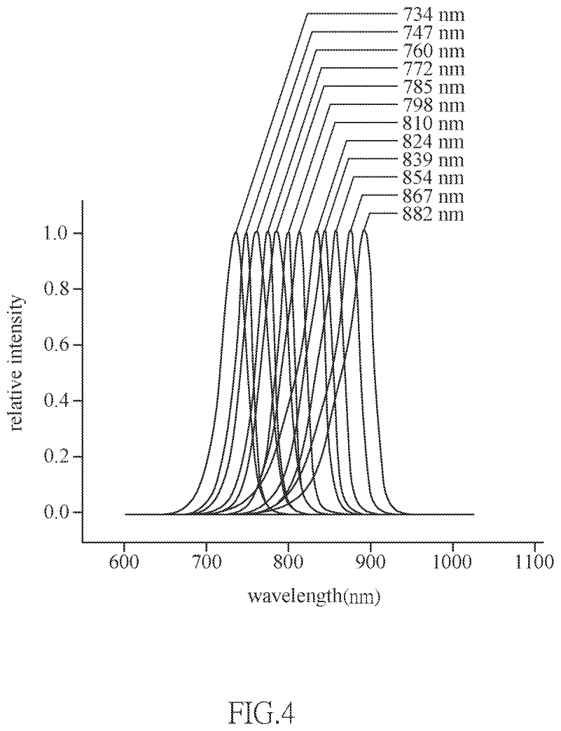

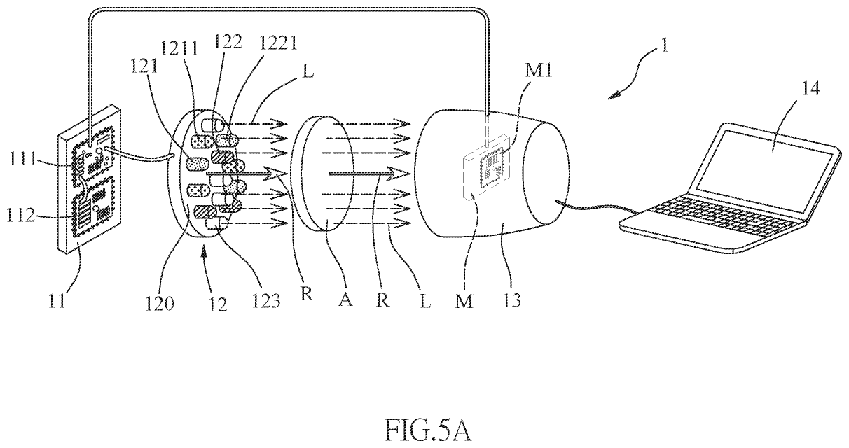

Refer to the third embodiment of FIG. 4, the third embodiment is modified from the first and second embodiments, and the similar parts of the third embodiment and the first, second embodiments are not described again. The difference between the third embodiment and the first embodiment is that the light emitting apparatus 12 comprises 12 LEDs. In FIG. 4, the light emission peak wavelengths of the 12 LEDs are 734 nm (first light emission peak wavelength), 747 nm, 760 nm, 772 nm (the fourth light emission peak wavelength), 785 nm, 798 nm, 810 nm (the second light emission peak wavelength), 824 nm, 839 nm, 854 nm (the fifth light emission peak wavelength), 867 nm and 882 nm (the third light emission peak wavelength) in increment order. Among the light emission peak wavelengths of the 12 LEDs, the wavelength differences of each two light emission peak wavelengths are respectively 13 nm, 13 nm, 12 nm, 13 nm, 13 nm, 12 nm, 14 nm, 15 nm, 15 nm, 13 nm and 15 nm. If the light emitting units of the first through third embodiments are LDs, the wavelength difference of the two adjacent light emission peak wavelengths can be larger than or equal to 1 nm, such as 1 nm.

At least one portions of the light emission peak wavelengths have full widths at half maximum being larger than 0 nm and less than or equal to 60 nm. Preferably, each of the full widths at half maximum of the light emission peak wavelengths is larger than 0 nm and less than or equal to 60 nm. For example, in the first through third embodiments, the light emission peak wavelengths of the 12 LEDs are 734 nm (first light emission peak wavelength), 747 nm, 760 nm, 772 nm (the fourth light emission peak wavelength), 785 nm, 798 nm, 810 nm (the second light emission peak wavelength), 824 nm, 839 nm, 854 nm (the fifth light emission peak wavelength), 867 nm and 882 nm (the third light emission peak wavelength) in increment order, and the full widths at half maximum of the first through fifth light emission peak wavelengths associated with the first through fifth light beams are larger than 0 nm and less than or equal to 60 nm, preferably, 15-50, and more preferably, 15-40 nm. The full widths at half maximum of other light emission peak wavelengths being 747 nm, 760 nm, 785 nm, 798 nm, 824 nm, 839 nm and 867 nm (see FIG. 4) are larger than 0 nm and less than or equal to 60 nm, preferably, 15-50, and more preferably, 15-40 nm. According to the experiment operation of the present disclosure, the full widths at half maximum of the light emission peak wavelengths in the first through third embodiments are 55 nm. If the light emitting units of the first through third embodiments are LDs, the full widths at half maximum of the light emission peak wavelengths can be larger than 0 nm and less than or equal to 60 nm, such as 1 nm.

The wavelength ranges of the two light emitting units with the two adjacent light emission peak wavelengths are non-overlapped. For example, if the full widths at half maximum of the light emission peak wavelengths in the first through third embodiments are 15 nm, each width of the wavelength range of the light emission peak wavelength is 40 nm (i.e. the difference between the maximum and minimum of the wavelength range), and two adjacent light emission peak wavelengths have the wavelength difference being 80 nm. For example, if the light emitting units are LDs, each full width at half maximum of the light emission peak wavelength is 1 nm, and the width of the wavelength range is 4 nm, two adjacent light emission peak wavelengths have the wavelength difference being 5 nm, and the wavelength ranges of the two LDs with the two adjacent light emission peak wavelengths are non-overlapped.

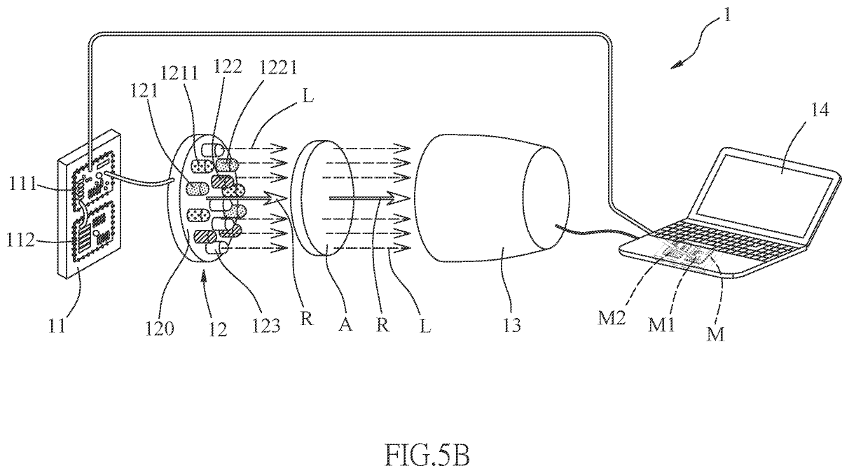

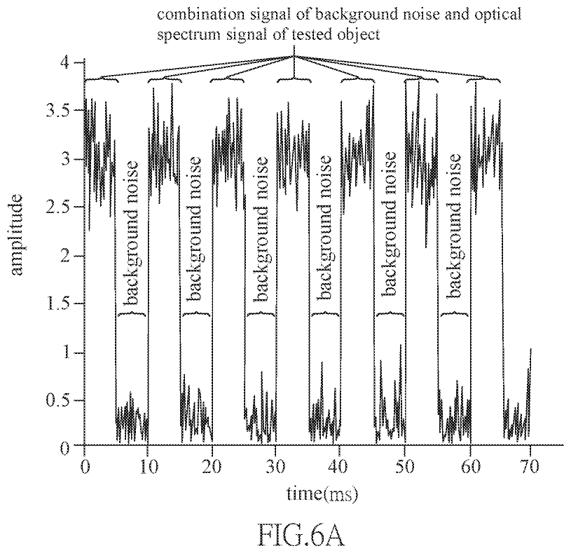

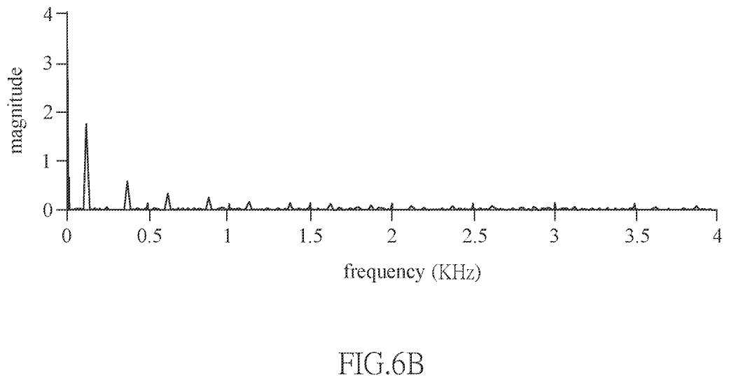

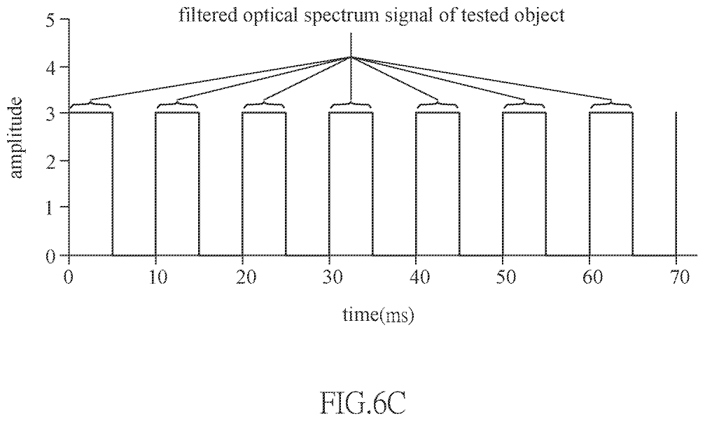

Preferably, when operating the spectrometer 1 in the first through third embodiment to measure the tested object A to generate the optical spectrum of the tested object A, as mentioned above, the light source controller 11 controls the LEDs to discontinuous radiate with the lighting frequencies. All of the lighting frequencies are identical to or different from each other or partial of the lighting frequencies are identical to or different from each other. The lighting frequency is 0.05-500 times/second. Associated with the lighting frequency, a time interval for turning on (lighting) the light emitting unit is 0.001-10 seconds. Associated with lighting frequency, a time interval for tuming off (slaking) the light emitting unit is 0.001-10 seconds. The period of the lighting frequency means the sum of the time intervals for sequentially turning on (lighting) and turning off (slaking) the light emitting unit once. The period of the lighting frequency is the reciprocal of the lighting frequency. In other words, the period of the lighting frequency can be interpreted as the sum of the time interval which the LED is turned on and the time interval which the LED is turned off after the LED is turned on. The time interval for turning on the LED is 0.001-10 seconds and the time interval for turning off the LED is 0.001-10 seconds. Preferably, the lighting frequency is 0.5-500 times/second, and more preferably, the lighting frequency is 5-500 times/second. The LEDs discontinuously radiates, and thus the effect of the thermal energy of the light emitted by the LEDs on the tested object A can be greatly reduced, and the qualitative change of the tested object A containing an organism can be avoided. The present disclosure is therefore particularly suitable for the tested object A that is sensitive to thermal energy, and more particularly suitable for the LED which emits the light with the wavelength range being the that of the near infrared light. A mathematical analysis module M is installed in the photodetector 13 (see FIG. 5A) or the computer 14 (see FIG. 5B), the mathematical analysis module M is electrically or signally connected to the photodetector 13 (see FIG. 5A), or the mathematical analysis module M is electrically or signally connected to the computer 14 (see FIG. 5B), and the mathematical analysis module M can be a software based or hardware based module. A signal collected by the photodetector 13 is transmitted to the mathematical analysis module M. When operating the spectrometer 1 to measure the tested object A to generate the optical spectrum of the tested object, the LEDs can be turned on or off at the same time with the same lighting frequency. In the time interval for turning on the light emitting unit, associated with the lighting frequency, the signal collected by the photodetector 13 is a combination signal of a background noise and an optical spectrum signal of the tested object. In the time interval for turning off the light emitting unit, associated with the lighting frequency, the signal collected by the photodetector 13 is the background noise. Referring to FIG. 6A, the spectrometer 1 is operated to make the LEDs discontinuously radiate with the lighting frequency to detect the tested object A, a combination signal of the background noise and the optical spectrum signal of the tested object A forms a time domain signal of the tested object A and an optical spectrum of the time domain signal associated with the tested object A. The optical spectrum signal of the tested object A and the background noise collected by the photodetector 13 are transmitted to the mathematical analysis module M, and the mathematical analysis module M processes the time domain signal of the tested object A to discard the background noise. For example, the mathematical analysis module M comprises a time domain/frequency domain transformation unit M1 (see FIG. 5A) for transforming the time domain signal of the tested object A to a frequency domain signal of the tested object A, the time domain/frequency domain transformation unit M1 is a Fourier transform unit for transforming the time domain signal of the tested object A to the frequency domain signal of the tested object A via a Fourier transformation. The frequency domain signal of the tested object A can be seen in FIG. 6B. The frequency domain signal of the tested object A comprises the frequency domain signal of the optical spectrum signal of the tested object A and the frequency domain signal of the background noise. In FIG. 6B, the frequency domain signal with the peak value at 0 Hz is less than frequency domain signal of the lighting frequency, and it is the frequency domain signal of the background noise. In FIG. 6B, the other frequency domain signal with other peak values except for the frequency domain signal with the peak value at 0 Hz (i.e. the frequency domain signal of the background noise) is the frequency signal of the optical spectrum signal of the tested object A. Preferably, in the frequency domain signal of the tested object A, the frequency domain signal being larger than or equal to the frequency signal of the lighting frequency is the frequency domain signal of the optical spectrum signal of the tested object A. The mathematical analysis module M discards the discards the frequency domain signal of the background noise and reserves the frequency domain signal of the optical spectrum signal of the tested object A, so as to achieve the filtering effect. Since the mathematical analysis module M discards the frequency domain signal of the background noise, the reserved frequency domain signal of the optical spectrum signal of the tested object A does not comprise the background noise. Thus, compared to the conventional spectrometer, the spectrometer 1 not only enhance the SNR of the optical spectrum of the tested object A, but also obtain the optical spectrum without background noise sine the spectrometer 1 discards and filters out the frequency domain signal of the background noise. Referring to FIG. 5A and FIG. 5B, the microcontroller unit 111 of the light source controller 11 is electrically or signally connected to the mathematical analysis module M, so as to transmit the lighting frequencies, the time intervals associated with the lighting frequency for turning on the LEDs and the time intervals associated with the lighting frequency for turning off the LEDs to the mathematical analysis module M, such that when the microcontroller unit 111 turns on or off the LEDs electrically connected to the microcontroller unit 111 according to the lighting frequencies, the time intervals associated with the lighting frequency for turning on the LEDs and the time intervals associated with the lighting frequency for turning off the LEDs, the mathematical analysis module M can correspond the time intervals associated with the lighting frequency for turning on the LEDs to the optical spectrum signal of the tested object, and correspond the time intervals associated with the lighting frequency for turning off the LEDs to the background noise.

It is noted that the discontinuous radiation waveform for presenting the lighting frequency of the LEDs can be a square wave, a positive sine wave or a negative sine wave.

In addition, the mathematical analysis module M can process the reserved frequency domain signal of the optical spectrum signal of the tested object A after filtering out, and transforms the frequency domain signal of the optical spectrum signal of the tested object A to a filtered time domain signal of the tested object A. The filtered time domain signal of the tested object A merely has the filtered optical spectrum signal of the tested object without background noise. For example, the mathematical analysis module M comprises a frequency domain/time domain transformation unit M2 (see FIG. 5B) for transforming the reserved frequency domain signal of the optical spectrum signal of the tested object A to the filtered time domain signal of the tested object A. The frequency domain/time domain transformation unit M2 is an inverse Fourier transform unit for transforming the reserved frequency domain signal of the optical spectrum signal of the tested object A to the filtered time domain signal of the tested object A via an inverse Fourier transformation, and the filtered time domain signal of the tested object A after filtering out can be seen in FIG. 6C. Compared to FIG. 6A and FIG. 6C, it is obvious to see that the filtered time domain signal of the tested object A in FIG. 6C is the filtered optical spectrum signal of the tested object A having the square waveform, and the filtered time domain signal of the tested object A does not have the background noise. In other words, the background noise in FIG. 6C is zero, and if dividing the filtered optical spectrum signal of the tested object A over the background noise, the obtained SNR is infinite. Therefore, the present disclosure enhance the SNR of the optical spectrum of the test results of the sample (tested object A), and the high test accuracy can be achieved. It is noted that, the mathematical analysis module M, the time domain/frequency domain transformation unit M1 and the frequency domain/time domain transformation unit M2 can be implemented by the hardware and/or the software. The mathematical analysis module M, the time domain/frequency domain transformation unit M1 and the frequency domain/time domain transformation unit M2 are electrically or signally connected to each other.

[Wavelength Resolution Test of Comparative and Application Examples]

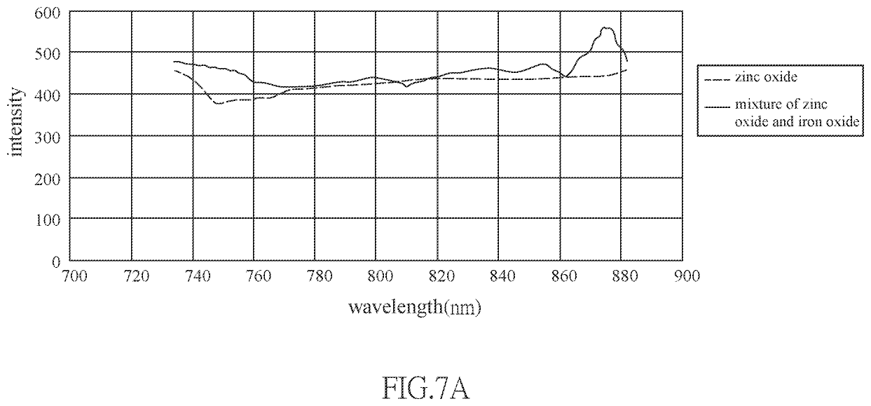

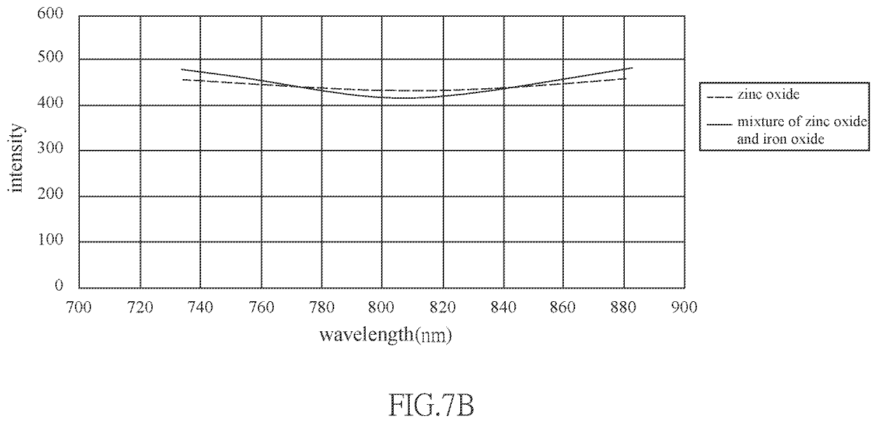

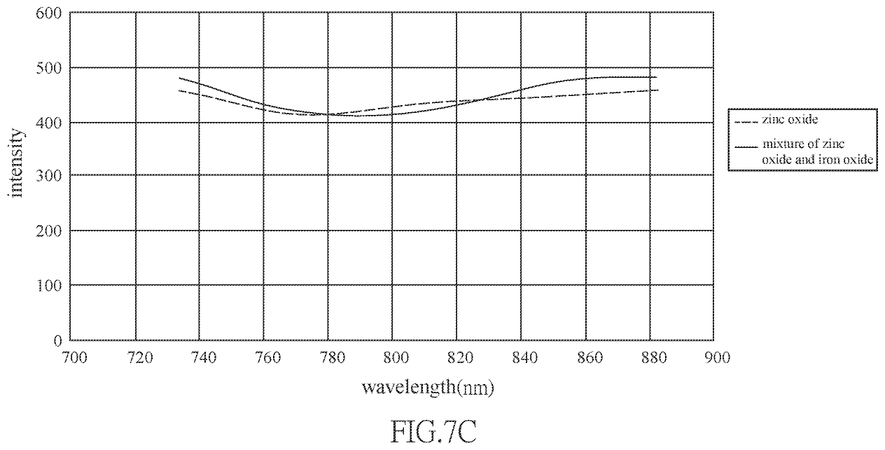

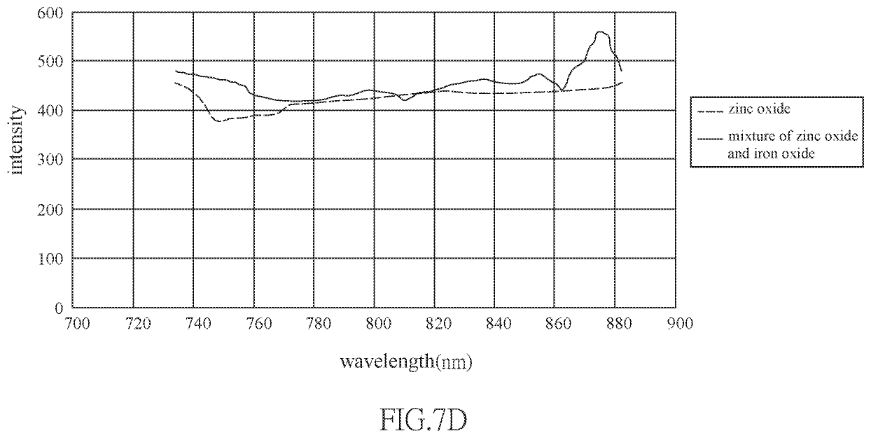

The comparative example 1 uses the conventional spectrometer of SE-2020-050-VNIR made by Oto photonics, which uses the tungsten halogen lamp as the light source and has a 1 nm wavelength resolution by using the grating. The conventional spectrometer is used to measure the reflection optical spectrum signal of the tested objects of the zinc oxide and the mixture of zinc oxide and iron oxide to obtain the optical spectrums of the tested objects, wherein one of the tested objects is a PVC (Polyvinyl Chloride) plate with a 2 cm thickness and coated by a zinc oxide coating with a 5 cm length and a 5 cm width, and the other one tested object a PVC plate with a 2 cm thickness and coated by the mixture coating with a 5 cm length and a 5 cm width. The obtained optical spectrum image data are processed and analyzed by a similarity (difference) process technology, i.e. SAM (Spectral Angle Match or Spectral Angle Mapping) process and analysis technology, so as to perform the similarity analysis of the zinc oxide and the mixture of the zinc oxide and iron oxide. The SAM analysis result is 96.00% (see FIG. 7A).

Application examples 1-3 correspond to the light emitting apparatuses and spectrometers of the first through third embodiments, the lighting frequency is 90.90 times/second, the time interval associated with the lighting frequency for turning on the light emitting unit is 1 ms, the time interval associated with the lighting frequency for turning off the light emitting unit is 10 ms, and the photodetector is the photodetector of SE-2020-050-VNIR made by Oto photonics. The spectrometers 1 are used to measure the reflection optical spectrum signal of the tested objects of the zinc oxide and the mixture of zinc oxide and iron oxide to obtain the optical spectrums of the tested objects, wherein one of the tested objects is a PVC plate with a 2 cm thickness and coated by a zinc oxide coating with a 5 cm length and a 5 cm width, and the other one tested object a PVC plate with a 2 cm thickness and coated by the mixture coating with a 5 cm length and a 5 cm width. The obtained optical spectrum image data are processed and analyzed by SAM process and analysis technology, so as to perform the similarity analysis of the zinc oxide and the mixture of the zinc oxide and iron oxide. The SAM analysis results are respectively 97.69% (FIG. 7B), 97.48% (FIG. 7C) and 96.54% (FIG. 7D), and all of them are close to the analysis result of 96.00% using the conventional spectrometer of the comparative example 1. Thus, wavelength resolution characteristics of the light emitting apparatus and the spectrometer in the first through embodiments are close to that of the conventional spectrometer. Thus, the wavelength resolution characteristics of the light emitting apparatuses and the spectrometers of the application examples 1-3 (i.e. the first through third embodiments) can replace wavelength resolution characteristics of the conventional spectrometer.

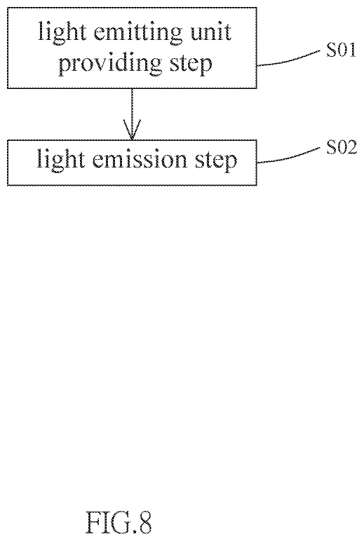

Thus, according to the light emitting apparatus 12 and spectrometer 1, FIG. 8 shows a flow chart of a light emitting method which comprises the a light emitting unit providing step SOI and a light emission step S02.

In the light emitting unit providing step S01: a plurality of light emitting units, each of them emits a light with a light emission peak wavelength and a wavelength range are provides, the wavelength ranges of the two light emitting units with the two adjacent light emission peak wavelengths are overlapped to form a continuous wavelength range which is wider than each of the wavelength ranges of the two light emitting units with the two adjacent light emission peak wavelengths, or alternatively, the wavelength ranges of the two light emitting units with the two adjacent light emission peak wavelengths are non-overlapped; the two adjacent light emission peak wavelengths have a wavelength difference being larger than or equal to 1 nm, and at least one portions of the light emission peak wavelengths have full widths at half maximum being larger than 0 nm and less than or equal to 60 nm. The light emitting unit can be the LED, VCSEL or LD. Preferably, the two adjacent light emission peak wavelengths have the wavelength difference being 1-80 nm, and more preferably, the two adjacent light emission peak wavelengths have the wavelength difference being 5-80 nm. Preferably, each of the full widths at half maximum of the corresponding light emission peak wavelength is 15-50 nm, and more preferably, each of the full widths at half maximum of the corresponding light emission peak wavelength is 15-40 nm.

In the light emission step S02: each of the light emitting units is controlled to discontinuously emit the light with a lighting frequency, wherein the lighting frequency is 0.05-500 times/second, associated with the lighting frequency, a time interval for turning on the light emitting unit is 0.001-10 seconds, and a time interval for turning off the light emitting unit is 0.001-10 seconds. Preferably, the lighting frequency is 0.5-500 times/second, and more preferably, 5-500 times/second.

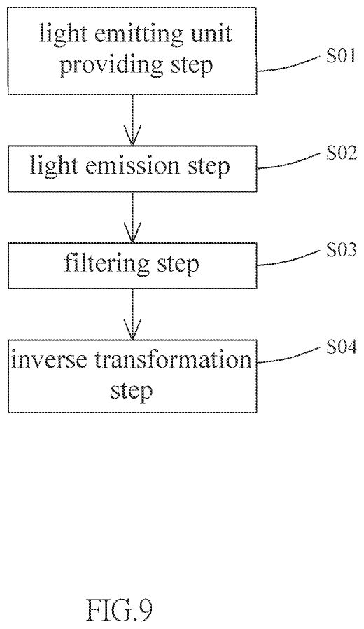

Further according to the light emitting apparatus 12, the spectrometer 1 and the light emitting method, FIG. 9 shows a flow chart of a spectrum detection method which comprises the light emitting unit providing step S01 and the light emission step S02 of the light emitting method, and further comprises a filtering step S03 and an inverse transformation step S04, wherein the steps S01-S04 are executed in order.

In the filtering step S03: an optical spectrum signal of the tested object and a background noise are received, in the time interval for turning on the light emitting unit, associated with the lighting frequency, the signal collected by the photodetector is a combination signal of the background noise and the optical spectrum signal of the tested object, and in the time interval for turning off the light emitting unit, associated with the lighting frequency, the signal collected by the photodetector is the background noise; the combination signal forms a time domain signal of the tested object, the time domain signal of the tested object is transformed to a frequency domain signal of the tested object via a Fourier transformation; the frequency domain signal of the tested object comprises a frequency domain signal of the optical spectrum signal of the tested object and a frequency domain signal of the background noise, the frequency domain signal of the background noise is discarded, and the frequency domain signal of the optical spectrum signal of the tested object is reserved.

In the inverse transformation stepS04: the reserved frequency domain signal of the optical spectrum signal of the tested object is transformed to the filtered time domain signal of the tested object via an inverse Fourier transformation.

[SNR Test]

Application example 4 uses the light emitting apparatus 12 and the spectrometer 1 of the third embodiment, the lighting frequency is 100 times/second, the time interval of the lighting frequency for turning on the LED is 5 ms, the time interval of the lighting frequency for turning off the LED is 5 ms, the period of the lighting frequency is 10 ms, and the photodetector is the photodetector of SE-2020-050-VNIR made by Oto photonics. The spectrometer 1 is used to measure the reflection optical spectrum signal of the tested object of the zinc oxide, wherein the tested objects is a PVC plate with a 2 cm thickness and coated by a zinc oxide coating with a 5 cm length and a 5 cm width, and the other one tested object a PVC plate with a 2 cm thickness and coated by the mixture coating with a 5 cm length and a 5 cm width. The spectrum detection method is used to detect the reflection optical spectrum signal. The optical spectrum signal of the tested object and the background noise form the time domain signal of the tested object and the time domain signal of the tested object, which are shown in FIG. 6A, wherein the discontinuous radiation waveform for presenting the lighting frequency of the LEDs is a square wave. Next, in the filtering step, the time domain signal of the tested object is performed with the Fourier transformation to be transformed to the frequency domain signal of the tested object, which can be seen in FIG. 6B. The frequency domain signal of the tested object is easily to be separated into the frequency domain signal of the optical spectrum signal of the tested object and the frequency domain signal of the background noise. For example, the period of the lighting frequency is 10 ms, and the light frequency is thus 100 Hz. In FIG. 6B, the frequency domain signal which larger than or equal to 100 Hz is the frequency domain signal of the optical spectrum signal of the tested object, and the frequency domain signal which is 0 Hz or less than 100 Hz is the frequency domain signal of the background noise. The filtering step discards the frequency domain signal of the background noise and reserves the frequency domain signal of the optical spectrum signal of the tested object. Next, the inverse transformation step transforms the reserved frequency domain signal of the optical spectrum signal of the tested object to the filtered time domain signal of the tested object (the discontinuous square wave in FIG. 6C) via the inverse Fourier transformation. As shown in FIG. 6C, there are no background noise (i.e. the background noise is zero), and the SNR is infinite, which achieve the high test or measure accuracy.

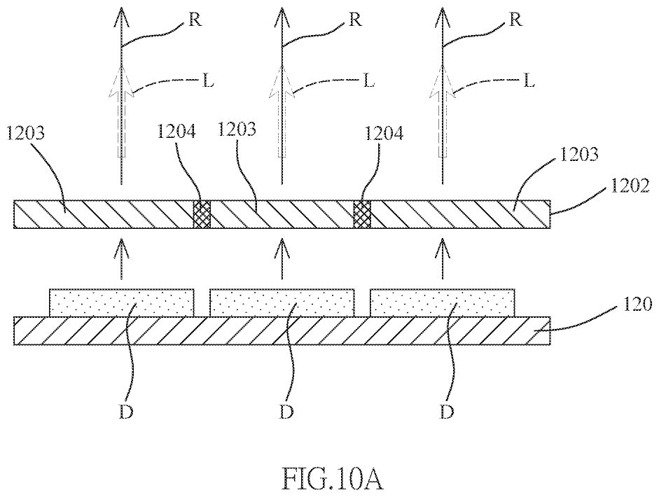

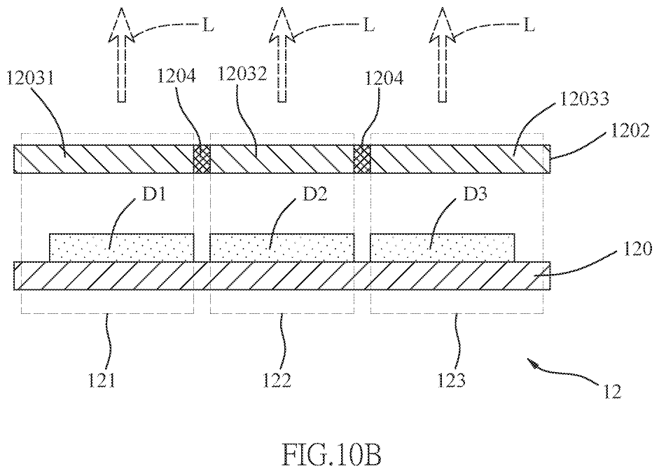

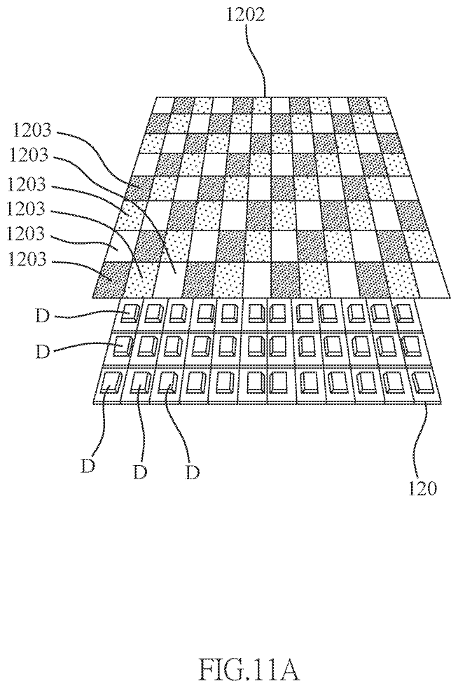

Refer to FIG. 10A, and it is noted that, in possible embodiments, each of the light emitting units comprises a light emitting die D, the light emitting die D is electrically connected to the circuit board 120, and top of the light emitting dies D is covered with a wavelength conversion layer 1202. The wavelength conversion layer 1202 is used to convert the primary light beam emitted by the light emitting die D to a secondary light beam having another wavelength. The wavelength conversion layer 1202 comprises a fluorescent layer of fluorescent powder (or phosphor), a quantum dot layer of quantum dots, or a nonlinear crystal layer of nonlinear crystal. The fluorescent powder can be yttrium aluminum garnet or other suitable fluorescent powder materials. The quantum dot material is a nanocrystalline semiconductor material, which can be synthesized from II-VI or III-V group compounds or other combinations, such as ZnS or CdSe. CsPbX₃ can also be used as the as the quantum dot material, wherein X is chlorine or bromine, Iodine, or any combination of the above; or CH₃NH₃PbX₃ can also be used as the quantum dot material, where X is chlorine, bromine, iodine, or any combination of the above. The quantum dot material can also be other suitable quantum dot material. The nonlinear crystal can be KTP (potassium titanyl phosphate), KDP (potassium dihydrogen phosphate), KBBF (potassium fluoroboronate), CBO (cesium triborate), CLBO (lithium cesium borate), BBO (barium beta borate), LBO (lithium triborate) and LB4 (lithium tetraborate), or other suitable nonlinear crystal. The wavelength conversion layer 1202 comprises wavelength conversion regions 1203, each of the wavelength conversion regions 1203 is disposed corresponding to the light path R associated with one of the light emitting dies D. Preferably, each of the wavelength conversion regions 1203 is disposed on the corresponding light emitting die D. The light emitted by the light emitting die D forms the light (i.e. the light beam L) with the light emission peak wavelength and the wavelength range after passing through the wavelength conversion region 1203. In other words, the light emitting unit is formed by the light emitting die D and the corresponding wavelength conversion region 1203, so as to emit the light (i.e. the light beam L) with the light emission peak wavelength and the wavelength range. All or at least one portion of the light emitting dies D are identical to each other, or all of the light emitting dies D are different from each other. The wavelength conversion layer 1202 is a film layer, the wavelength conversion regions 1203 are consecutive to form the film layer, or the two adjacent wavelength conversion regions 1203 of the film layer are separated from a spacer 1204. The wavelength conversion layer 1202 contacts the light emitting die D, or the wavelength conversion laver 1202 does not contact the light emitting die D. Preferably, the wavelength conversion layer 1202 does not contact the light emitting die D. The wavelength conversion regions 1203 comprise the fluorescent powder, and all or partial of the wavelength conversion regions 1203 comprise identical or different fluorescent powders. The wavelength conversion regions 1203 can comprise the quantum dot material, and all or partial of the wavelength conversion regions 1203 comprise identical or different quantum dot material. The wavelength conversion regions 1203 can comprise the nonlinear crystal, and all or partial of the wavelength conversion regions 1203 comprise identical or different nonlinear crystal.

In the embodiment of FIG. 10B, the light emitting apparatus 12 comprises three light emitting units which are the first LED 121, the second LED 122 and the third LED 123. The first LED 121, the second LED 122 and the third LED 123 comprise a first light emitting die D1, a second light emitting die D2 and a third light emitting die D3 respectively, and the first light emitting die D1, the second light emitting die D2 and the third light emitting die D3 are identical to each other. The first light emitting die D1, the second light emitting die D2 and the third light emitting die D3 are electrically connected to the circuit board 120. The top of the first light emitting die D1, the second light emitting die D2 and the third light emitting die D3 is covered by the wavelength conversion layer 1202, and the wavelength conversion layer 1202 comprise a first wavelength conversion region 12031, a second wavelength conversion region 12032 and a third wavelength conversion region 12033. The wavelength conversion layer 1202 does not contact the first light emitting die D1, the second light emitting die D2 and the third light emitting die D3. The first wavelength conversion region 12031 is disposed on the first light emitting die D1, the second wavelength conversion region 12032 is disposed on the second light emitting die D2, and the third wavelength conversion region 12033 is disposed on the third light emitting die D3. The first wavelength conversion region 12031, the second wavelength conversion region 12032 and the third wavelength conversion region 12033 comprise different fluorescent powder. The first LED 121 is formed by the first light emitting die D1 and the corresponding first wavelength conversion region 12031, the second LED 122 is formed by the second light emitting die D2 and the corresponding second wavelength conversion region 12032, and the third LED 123 is formed by the third light emitting die D3 and the corresponding third wavelength conversion regions 12033. Thus, the light emitted by the first light emitting die D1 passes through the first wavelength conversion region 12031 to form the first light beam, the light emitted by the second light emitting die D2 passes through the second wavelength conversion region 12032 to form the second light beam, and the light emitted by the third light emitting die D3 passes through the third wavelength conversion region 12033 to form the third light beam.

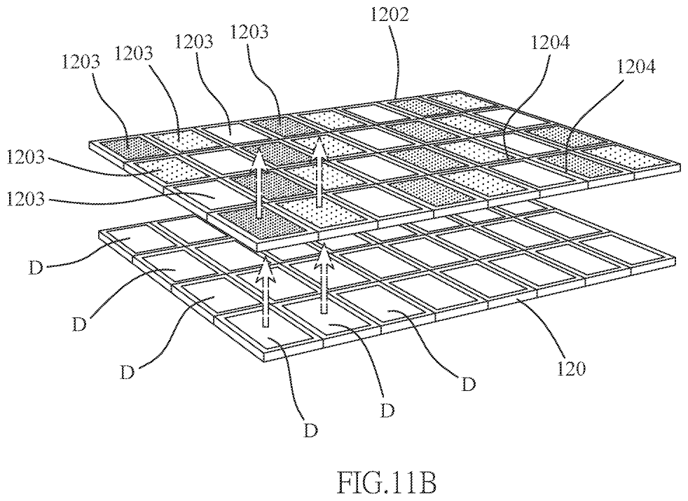

Refer to FIG. 11A and FIG. 11B, the circuit board 120 is an array substrate, and the light emitting dies D are formed on the array substrate in matrix. The wavelength conversion regions 1203 of the wavelength conversion layer 1202 are disposed on the array substrate in matrix. Each of the wavelength conversion regions 1203 disposed on the corresponding light emitting die D. In FIG. 11B, the adjacent wavelength conversion regions 1203 are separated by the spacer 1204.

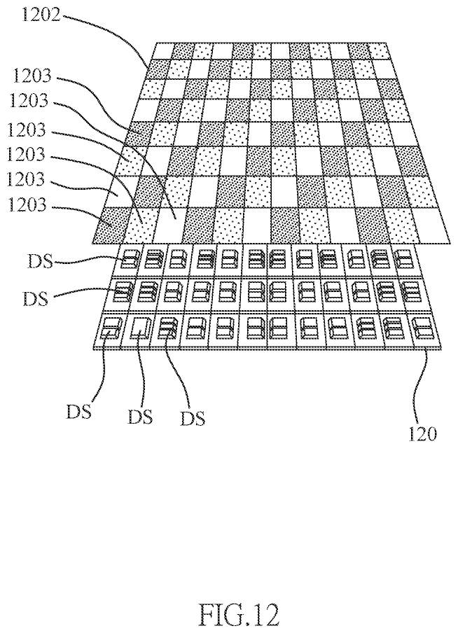

Refer to FIG. 12, in other possible embodiments, each of the light emitting units comprises a light emitting die assembly DS, the light emitting die assembly DS comprises one or more light emitting dies D. and the number of the light emitting dies D of one light emitting die assembly DS may be identical to or different from the that of another one light emitting die assembly DS. The top of the plurality of the light emitting die assembly DS is covered by the wavelength conversion layer 1202. The wavelength conversion layer 1202 comprises the wavelength conversion regions 1203, each of the wavelength conversion regions 1203 is disposed corresponding to one light emitting die assembly DS, and preferably, each of the wavelength conversion regions 1203 is disposed on the light emitting die assembly DS. The circuit board 120 is an array substrate, the plurality of the light emitting die assembly DS are disposed on the array substrate in matrix, and the circuit board 120 can independently control each of the light emitting dies D of the light emitting die assembly DS to be turned on or off. The wavelength conversion regions 1203 of the wavelength conversion layer 1202 are disposed on the array substrate in matrix, and each wavelength conversion region 1203 is disposed on the light emitting die assembly DS.

Refer to FIG. 13A through 13C at the same time. In FIG. 13A, when the thickness of the tested object A is large enough to make the light beam L unable to pass through the tested object A, but it still needs to measure the inner optical signal of the tested object A, the spectrometer 1 can measure the reflection optical spectrum signals of different depths of the tested object A. The light emitting apparatus 12 and the photodetector 13 are disposed on the same side of the tested object A. For example, in FIG. 13A, the light emitting apparatus 12 and the photodetector 13 are disposed on the top side of the tested object A, so as measure the reflection optical spectrum of the tested object A. The light beam L emitted by the light emitting apparatus 12 comprises an emission light beam La, the emission light beam La is radiated to a surface reflection point A1 of the top surface A0 of the tested object A, and the emission light beam La is reflected at the surface reflection point A1 to form a surface reflection light beam Le. The photodetector 13 is disposed on the propagation path of the surface reflection light beam Le, and thus the surface reflection light beam Le is received the photodetector 13. The photodetector 13 converts the surface reflection light beam Le into a surface optical spectrum signal of the tested object A, and the surface optical spectrum signal of the tested object A is transmitted to the computer 14. The computer 14 is used to convert the surface optical spectrum signal of the tested object A to a surface optical spectrum of the tested object A. Thus, the components of the surface material of the tested object A can be determined according to the surface optical spectrum of the tested object A. Refer to FIG. 13B, one portion of the emission light beam La passes through top surface A0 and is refracted to form an inner refraction light beam Laf which enters the interior of the tested object A. Due to the wavelength characteristics of the inner refraction light beam Laf, the inner refraction light beam Laf enters the interior of the tested object A and reaches the internal diffuse point A1f to form a penetration depth Af. The penetration depth Af means a longest distance from the top surface A0 to the interior of the tested object A which the inner refraction light beam Laf can reach. The inner refraction light beam Laf forms an inner diffuse light beam Lef at the internal diffuse point A1f with the penetration depth Af. The inner diffuse light beam Lef passing through a surface refraction point A2 of the top surface A0 is refracted to form an inner light beam Lf of the tested object A, the photodetector 13 is disposed on a propagation path of the inner light beam Lf of the tested object A, and the inner light beam Lf of the tested object A is received by the photodetector 13. The photodetector 13 converts the inner light beam Lf of the tested object A to the inner optical spectrum signal of the tested object A. The inner optical spectrum signal of the tested object A is transmitted to the computer 14. The computer 14 is used to convert the inner optical spectrum signal of the tested object A to an inner optical spectrum of the tested object A. Thus, the components of the inner material of the tested object A can be determined according to the inner optical spectrum of the tested object A. Refer to FIG. 13C, the spectrometer 1 has a light blocking part B which the light beam cannot pass through, and the light blocking part B contacts the top surface A0 and disposed between the surface reflection point A1 and the surface refraction point A2, which makes the surface reflection light beam Le unable to be received by the photodetector 13. Thus, it makes sure that the light beam received by the photodetector 13 is the inner light beam Lf of the tested object A without being affected by the surface reflection light beam Le. It is noted that, the spectrum detection method utilizes the spectrometer to detect the components of the inner material of the tested object A.

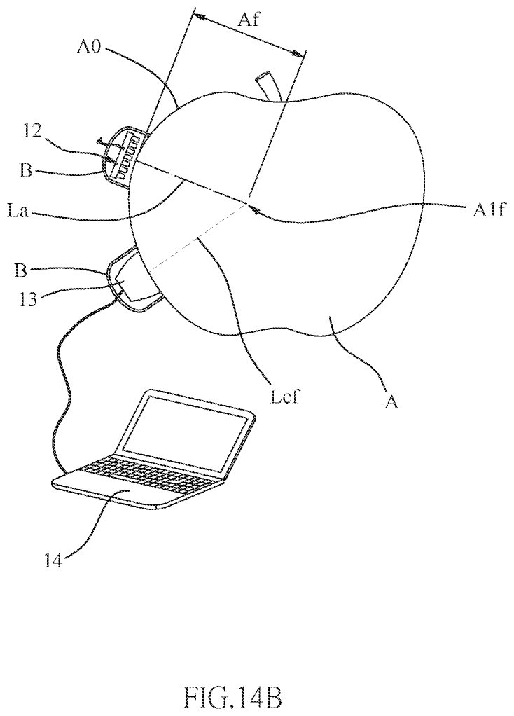

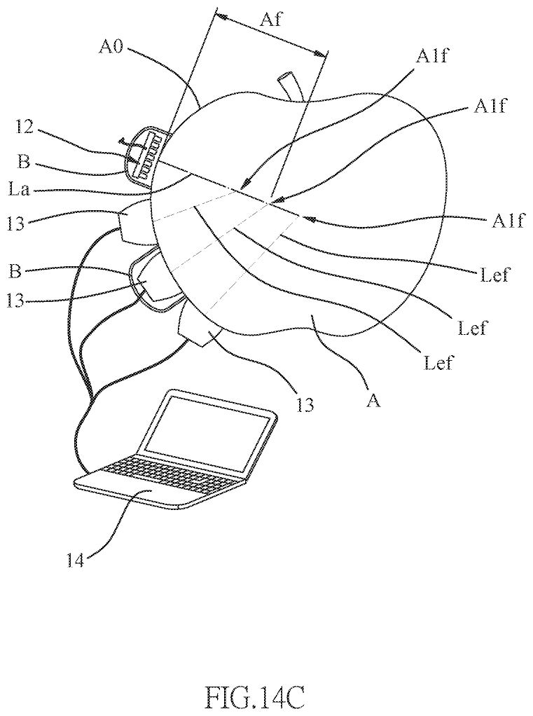

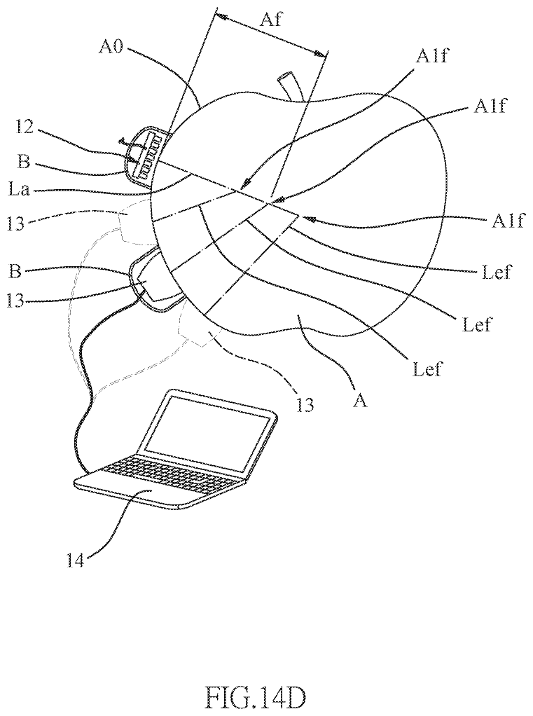

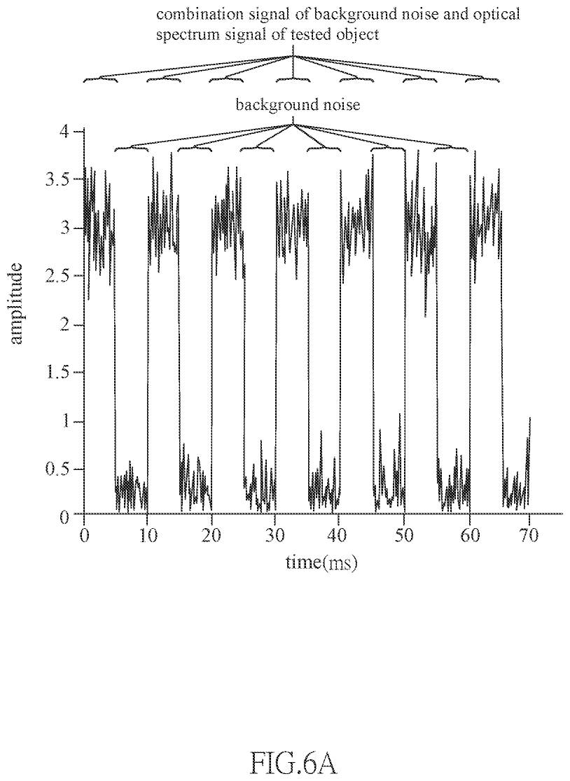

Refer to FIG. 14A through FIG. 14D at the same time. Another way to avoid the effect of the surface reflection light beam Le can be seen in FIG. 14A. In FIG. 14A, the top surface A0 is a curved surface, and the tested object A can be the object with the curved surface, for example, the apple of the fruit. The top surface A0 the apple peel, the light emitting apparatus 12 closely contacts the top surface, such that the emission light beam La is radiated to a curvature center of the top surface A0 (apple peel), the emission light beam La is not refracted and directly passes through the top surface A0, and then the emission light beam La enters the interior of the tested object A (pulp section). The emission light beam La passes through the interior of tested object A and reaches the [symbol] internal diffuse point A1f to form the penetration depth Af, and then is diffused at the internal diffuse point A1f to form the inner diffuse light beam Lef. The inner diffuse light beam Lef passes through the top surface A0 to form the inner light beam Lf of the tested object A, the photodetector 13 is disposed on a propagation path of the inner light beam Lf of the tested object A, and the inner light beam Lf of the tested object A is received by the photodetector 13. The photodetector 13 converts the inner light beam Lf of the tested object A to the inner optical spectrum signal of the tested object A (optical spectrum signal of the pulp section). The inner optical spectrum signal of the tested object A is transmitted to the computer 14. The computer 14 is used to convert the inner optical spectrum signal of the tested object A to an inner optical spectrum of the tested object A (optical spectrum of the pulp section). Thus, the components of the inner material of the tested object A (components of the pulp section) can be determined according to the inner optical spectrum of the tested object A. It is noted that since the light emitting apparatus 12 closely contacts the top surface A0, the photodetector 13 does not receive the emission light beam La, and this makes sure that the photodetector 13 merely receives the inner light beam of the tested object Lf without being affected by the emission light beam La. Of course, the light blocking part B of a mask type can mask the light emitting apparatus 12 and expose the exit of the emission light beam La, and the light blocking part B closely contacts the top surface A0. According to such configuration, this further makes sure the photodetector 13 merely receives the inner light beam Lf of the tested object A without being affected by the surface reflection light beam (see FIG. 14A). Refer to FIG. 14B, the photodetector 13 closely contacts the top surface A0, and the inner diffuse light beam Lef passes through the top surface A0 and forms the inner light beam Lf of the tested object A (see FIG. 14B). The photodetector 13 is disposed on a propagation path of the inner light beam Lf of the tested object A, and the inner light beam Lf of the tested object A is received by the photodetector 13. The photodetector 13 converts the inner light beam Lf of the tested object A to the inner optical spectrum signal of the tested object A (optical spectrum signal of the pulp section). The inner optical spectrum signal of the tested object A is transmitted to the computer 14. The computer 14 is used to convert the inner optical spectrum signal of the tested object A to an inner optical spectrum of the tested object A (optical spectrum of the pulp section). Thus, the components of the inner material of the tested object A (components of the pulp section) can be determined according to the inner optical spectrum of the tested object A. Of course, the light blocking part B of a mask type can mask the photodetector 13 and expose the entrance of the inner light beam Lf of the tested object A, and the light blocking part B closely contacts the top surface A0. According to such configuration, this further makes sure the photodetector 13 merely receives the inner light beam Lf of the tested object A without being affected by the surface reflection light beam or other light beam.

In addition, as mentioned above, the light emitting apparatus 12 at least comprises a plurality of light emitting units, and each of them emits a light with a light emission peak wavelength and a wavelength range. The light emission peak wavelength or the wavelength range is 300-2500 nm. The light emitting unit can be the LED for example, and the LEDs can be turned on or off according to the actual requirements at the same time, or one or partial LEDs are selected to turned on or off, or the LEDs are turned on or off in turn, or the LEDs are turned on or off by using one of the above manners with the lighting frequency. The light beam L (see FIG. 1) emitted by the light emitting apparatus 12 can be the emission light beam La, and the emission light beam La comprises the light with the wavelength range. Refer to FIG. 14C, the emission light beam La comprises different lights with different wavelength ranges, and the spectrometer 1 has the multiple photodetectors 13, the photodetectors 13 are disposed on the different positions of the top surface A0. The emission light beam La comprises the lights of different wavelength ranges passes through the interior of the tested object A (pulp section), and each of the lights with the different wavelength ranges reaches the internal diffuse point A1f to form the penetration depth Af. The lights of the emission light beam La are diffused at the internal diffuse points A1f to form the inner diffuse light beams Lef, and the penetration depths Af are usually different from each other. Each inner diffuse light beam Lef passes through the top surface A0 to form the inner light beam Lf of the tested object A (not shown in FIG. 14C), and each of the photodetectors 13 are disposed on the propagation path of the inner light beam Lf of the tested object A. The inner light beams Lf of the tested object A are received by the photodetectors 13 respectively. The photodetectors 13 respectively convert inner light beams Lf of the tested object A of the different penetration depths Af to the inner optical spectrum signals of the tested object A (the inner optical spectrum signals of different depth of the pulp section). The inner optical spectrum signals of the tested object A are transmitted to the computer 14. The computer 14 is used to convert the inner optical spectrum signals of the tested object A to inner optical spectrums of different penetration depths Af of the tested object A (optical spectrums of the different depths of the pulp section). The computer merges inner optical spectrums of different penetration depth Af of the tested object A to a complete inner optical spectrum of the tested object A. Thus, the components of the inner material of the tested object A (components of the pulp section) can be determined according to the inner optical spectrums or the complete inner optical spectrum of the tested object A. Refer to FIG. 14, the spectrometer 1 can have merely one photodetector 13, and when the light emitting apparatus 12 emits the emission light beam La, the photodetector 13 is disposed on different positions of the top surface A0 in turn, wherein the different positions correspond the propagation paths of the inner light beams Lf of the tested object A. Thus, the inner light beams Lf of the tested object A corresponding to different penetration depths Af are received by the photodetector 13 in turn.

From the above descriptions, compared to the current technology and product, the light emitting apparatus, the light emitting method, the spectrometer and the spectrum detection method have the analysis result for a sample being close to the high analysis results of the conventional tungsten halogen spectrometer, and at the same time, the present disclosure improves the signal-to-noise ratio in the optical spectrum of the test results of the sample, so as to achieve the high accuracy of the test.

To sum up, the light emitting apparatus, the light emitting method, the spectrometer and the spectrum detection method of the present disclosure can achieve the dedicated effect and are not disclosed by the prior art before the present disclosure is submitted. That is, the present disclosure has patentability, and allowance of the present disclosure is respectfully requested by the Applicant.

The above-mentioned embodiments only exemplarily illustrate the principle and efficacy of the present disclosure, and are not intended to limit the present disclosure. Anyone who is familiar with this technology can modify or change the above embodiments without violating the spirit and scope of the present disclosure. Therefore, all equivalent modifications or changes made by those with ordinary knowledge in the technical field without departing from the spirit and technical ideas disclosed in this present disclosure should still be fall within the claim scope of the present disclosure.

1. A spectrometer, at least comprising:
a light source controller;
a light emitting apparatus;
one or more photodetectors; and
a computer;
wherein the light source controller is electrically connected to the light emitting apparatus, the photodetector is electrically connected to the computer, the photodetector receives a light beam emitted by the light emitting apparatus, and a propagation path of the light beam between the light emitting apparatus and photodetector forms a light path;
wherein the light emitting apparatus comprises a plurality of light emitting units, each of them emits a light with a light emission peak wavelength and a wavelength range;
wherein the wavelength ranges of the two light emitting units with the two adjacent light emission peak wavelengths are overlapped to form a continuous wavelength range which is wider than each of the wavelength ranges of the two light emitting units with the two adjacent light emission peak wavelengths, or alternatively, the wavelength ranges of the two light emitting units with the two adjacent light emission peak wavelengths are non-overlapped; the two adjacent light emission peak wavelengths have a wavelength difference being larger than or equal to 1 nm, at least one portions of the light emission peak wavelengths have full widths at half maximum being larger than 0 nm and less than or equal to 60 nm;
wherein a mathematical analysis module is installed in the photodetector or the computer, the mathematical analysis module is electrically or signally connected to the photodetector or the computer, the mathematical analysis module is a hardware or software based module, and a signal collected by the photodetector is transmitted to the mathematical analysis module;
wherein the light source controller comprises a microcontroller unit, at least one lighting frequency is generated by a clock generator or a clock generation module integrated in the microcontroller unit, a signal of the lighting frequency is then transmitted to the microcontroller unit; the microcontroller unit is electrically or signally connected to the mathematical analysis module, so as to transmit the lighting frequencies, a time interval associated with the lighting frequency for turning on the light emitting unit and a time interval associated with the lighting frequency for turning off the light emitting unit to the mathematical analysis module, the microcontroller unit turns on or off the light emitting unit electrically connected to the microcontroller unit according to the lighting frequency, the time interval associated with the lighting frequency for turning on the light emitting unit and the time interval associated with the lighting frequency for turning off the light emitting unit;
wherein in the time interval for turning on the light emitting unit, associated with the lighting frequency, the signal collected by the photodetector is a combination signal of a background noise and an optical spectrum signal of the tested object; in the time interval for turning off the light emitting unit, associated with the lighting frequency, the signal collected by the photodetector is the background noise; the combination signal forms a time domain signal of the tested object, and the mathematical analysis module comprises a time domain/frequency domain transformation unit for transforming the time domain signal of the tested object to a frequency domain signal of the tested object.

2. The spectrometer of claim 1, wherein the light emitting unit is a light emitting diode, a vertical-cavity surface-emitting laser or a laser diode.

3. The spectrometer of claim 2, wherein each of the light emitting units discontinuously emits the light with the lighting frequency, and all of the lighting frequencies are identical to or different from each other, or partial of the lighting frequencies are identical to or different from each other.

4. The spectrometer of claim 3, wherein the lighting frequency is 0.05-500 times/second.

5. The spectrometer of claim 4, wherein associated with the lighting frequency, the time interval for turning on the light emitting unit is 0.001-10 seconds.

6. The spectrometer of claim 5, wherein associated with lighting frequency, the time interval for turning off the light emitting unit is 0.001-10 seconds.

7. The spectrometer of claim 6, wherein the two adjacent light emission peak wavelengths have the wavelength difference being 1-80 nm.

8. The spectrometer of claim 7, wherein the two adjacent light emission peak wavelengths have the wavelength difference being 5-80 nm.

9. The spectrometer of claim 6, wherein each of the full widths at half maximum of the corresponding light emission peak wavelength is 15-50 nm.

10. The spectrometer of claim 9, wherein each of the full widths at half maximum of the corresponding light emission peak wavelength is 15-40 nm.

11. The spectrometer of claim 2, wherein the light emitting unit comprises a light emitting die, and the light emitting dies are covered by a wavelength conversion layer, the wavelength conversion layer comprises a plurality of wavelength conversion regions, each of the wavelength conversion regions corresponds to one of the light emitting dies.

12. The spectrometer of claim 11, wherein all or partial of the light emitting dies are identical to each other, or all of the light emitting dies are different from each other.

13. The spectrometer of claim 12, wherein all or partial of the wavelength conversion regions comprise identical or different fluorescent powders, quantum dot materials or nonlinear crystals.

14. The spectrometer of claim 13, wherein the wavelength conversion layer is a film layer, and the wavelength conversion regions are consecutive to form the film layer; or, the two adjacent wavelength conversion regions of the film layer are separated from a spacer.

15. The spectrometer of claim 14, wherein the time domain/frequency domain transformation unit is a Fourier transform unit for transforming the time domain signal of the tested object to the frequency domain signal of the tested object via a Fourier transformation.

16. The spectrometer of claim 14, wherein the frequency domain signal of the tested object comprises a frequency domain signal of the optical spectrum signal of the tested object and a frequency domain signal of the background noise, the mathematical analysis module discards the frequency domain signal of the background noise and reserves the frequency domain signal of the optical spectrum signal of the tested object, the mathematical analysis module further comprises a frequency domain/time domain transformation unit for transforming the reserved frequency domain signal of the optical spectrum signal of the tested object to the filtered time domain signal of the tested object.

17. The spectrometer of claim 16, wherein the frequency domain/time domain transformation unit is an inverse Fourier transform unit for transforming the reserved frequency domain signal of the optical spectrum signal of the tested object to the filtered time domain signal of the tested object via an inverse Fourier transformation.
